(19) United States
(12) Patent Application Publication
(10) Pub. No.: US 2019/0355276 A1
(43) Pub. Date: Nov. 21, 2019

(54) TACTILE COMPUTING DEVICE

(71) Applicant: ARAZIM MOBILE LTD., Jerusalem (IL)

(72) Inventors: COHEN Rami, Jerusalem (IS); SHARF Sharon, Kiryat Atta (IS); MIKULIZKY David, Kiryat Motzkin (IS)

(73) Assignee: Arazim Mobile Ltd., Jerusalem (IL)

(21) Appl. No.: 16/476,062

(22) PCT Filed: Jan. 2, 2018
(86) PCT No.: PCT/IL2018/050006

§ 371 Date: Jul. 3, 2019

Related U.S. Application Data
(60) Provisional application No. 62/441,601, filed on Jan. 3, 2017.

(51) Int. Cl. G09B 21/00; G09B 21/02; B81B 7/00

(52) U.S. Cl. CPC G09B 21/004; G09B 21/008; G09B 21/025; B81B 2201/045; G09B 21/007; B81B 7/0003; G09B 21/009

(57) ABSTRACT

A tactile computerized device which includes a tactile interface apparatus for displaying information and receive inputs from a user, comprising a touchscreen for receiving inputs from the user and for displaying visual data; an array of tactile pins that can It be pushed to one or more levels to protrude above the touchscreen and pulled below the touchscreen, via holes in the surface, by one or more actuators, the tactile pins, when protruding above the surface, are being capable of representing the information in the form of tactile pixels that create embossed images above the surface; actuators, for individually controlling the movement of each tactile pin and holding each the tactile pins in a desired level; a controller for converting information to be displayed that is received from the computerized device, to activation signals, activating the actuators to individually control the level of each tactile pin, such that tactile pins that protrude above the touchscreen and the remaining tactile pins being below the touchscreen will represent the information to be displayed; refreshing the displayed information by updating the level of each tactile pin; following groping of protruding tactile pins, receiving inputs from the user in the form of touching a desired location on the touchscreen.

### FIELD OF THE INVENTION

The present invention relates to the field of computing aids. More particularly, the invention relates to a tactile computing device that enables users with impaired vision (who cannot see because of blindness, limited view or absence of present ability to watch) to be able to sense computerized information with their fingers and operate online applications.

### BACKGROUND OF THE INVENTION

Blindness and visual impairments have many social and personal aspects. Blind population and users with impaired vision suffer from many limitations regarding their ability to interact with computers. Even though they are able to hear (receive voice data from a computer) and speak (provide inputs to a computer), their ability to understand and interact with graphical information is at most, very limited. Even when interacting with running applications such as word processors, spreadsheets, browsers or games) a user with impaired vision cannot indicate his choice, such as clicking a mouse or touching a touchscreen. Moreover, there is no ability for user to build correlation between graphical and numerical information. This leads to a situation in which users with impaired vision lack the ability to join the workforce or to participate in social networking.

The PAC Mate Omni (by Freedom Scientific, Inc., St. Petersburg, Fla., U.S.A.) is a versatile Braille and Speech portable computer, which provides speech or Braille access to Windows® Mobile® applications for people who are blind. However, it is costly (about $3600) and cannot display graphic information, icons etc.

Graphic display Hyperbraille S 620 device (by Metec A G, Stuttgart, Germany) enables displaying of graphic information using Braille dots. However, it is extremely expensive (about $15,000) and has very low resolution. Therefore, it is very difficult for blind people to understand the nature of the displayed information.

Another existing solution is Text-to-speech software, which converts digital text to speech and vice versa. However, users can receive only small parts of information which are not graphical. Therefore, considering the fact that most applications display graphical information, these small parts are practically meaningless.

Currently existing tactile solutions for people who cannot see (whether due to blindness, impaired vision or temporary inability to watch), are limited in their ability to communicate high definition information to users. Also, these solutions are not able to display graphical information in a sufficient manner and lack the ability to show embossed items. These Existing solutions are too expensive and do not display the information in a way that is meaningful to users with impaired vision. In addition, current solutions can only display the information but do not allow for any modifications of the information that is displayed.

It is therefore an object of the present invention to provide a computing device with a rich tactile interface, which will allow people with impaired vision or with limited ability to look at the screen (e.g. while driving) to utilize applications running on the computing device in a much broader way.

It is another object of the present invention to provide a computing device with a tactile interface, which will allow people with impaired vision to easily understand graphical information provided by online services and applications and operate them accordingly.

Other objects and advantages of the invention will become apparent as the description proceeds.

### SUMMARY OF THE INVENTION

The present invention is directed to a tactile display apparatus for displaying information received from a computerized device (such as a desktop computer, a laptop, a tablet, a smartphone), which comprises:
a) an array of tactile pins that can be pushed to one or more levels to protrude above a rigid surface and pulled below the rigid surface, via holes in the surface, by one or more actuators, the tactile pins, when protruding above the surface, are being capable of representing the information in the form of tactile pixels that create embossed images above the surface;
b) one or more actuators (implemented, for example by MEMS technology), connected to each of the tactile pins, and being capable of individually controlling the movement of each tactile pin and holding each the tactile pins in a desired level;
c) a controller consisting of a processor, a memory and dedicated software, for:
   c.1) converting information to be displayed that is received from the computerized device, to activation signals;
   c.2) activating the actuators, by the activation signals, to individually control the level of each tactile pin, such that tactile pins that protrude above the rigid surface and the remaining tactile pins being below the rigid surface will represent the information to be displayed;
   c.3) holding all tactile pins in place, as long as the information to be displayed has not been changed; and
   c.4) whenever receiving, from the computerized device, updated information to be displayed, refreshing the displayed information by updating the level of each tactile pin, such that tactile pins that protrude above the rigid surface and the remaining tactile pins being below the rigid surface will represent the updated information.

The tactile display apparatus may further comprising controllable holders (implemented, for example by MEMS technology) for holding the tactile pins in place by applying lateral force on the tactile pins, as long as the information to be displayed has not been changed.

The information to be displayed, received from a computerized device, may be the form of video signals.

The displayed information may be textual, graphical or a combination thereof and may include:
contour lines of graphical objects;
a combination of contour lines of graphical objects and textual characters contained therein;
grids of a graph;
bars of a histogram; and
graphical data segments.

The protruding pins may serve as “tactile pixels” representing the information to be displayed.

The information to be displayed may be refreshed according to a predetermined resolution being the distance between neighbouring tactile pins that protrude above the rigid surface.

Different levels of pins may be used to:
create a sense of different colors;
create gradual change of the height, to thereby create a sense of three-dimensional objects;
represent curvatures of graphic information.

In one embodiment, the rigid surface is a touchscreen, which is connected to the computerized device and form a tactile interface apparatus, which is adapted to:
a) display visual information received from the computerized device; and
b) following groping of protruding tactile pins, receive inputs from the user in the form of touching a desired location on the touchscreen.

The tactile interface apparatus may further comprise a voice controller, for:
providing voice feedback to the user regarding inputs be provided or his location on the touchscreen;
providing voice guidance to the user regarding how to provide inputs.

Tactile pins may define tactile contour lines of a touchpad, in which the user can drag his finger to emulate movements of a mouse cursor, or of a virtual key of a keyboard or a virtual button.

Tactile pins inside the contour lines may be controlled to define a symbol representing one of the following:
graphical information;
textual information;
Braille characters;
ELIA FRAMES™ characters;
programmable shortcuts;
tactile toolbar;
tactile keys of a virtual keyboard.

The present invention is also directed to a tactile computerized device which comprises a tactile interface apparatus for displaying information and receive inputs from a user, comprising:
a) a touchscreen for receiving inputs from the user and for displaying visual data;
b) an array of tactile pins that can be pushed to one or more levels to protrude above the touchscreen and pulled below the touchscreen, via holes in the surface, by one or more actuators, the tactile pins, when protruding above the surface, are being capable of representing the information in the form of tactile pixels that create embossed images above the surface;
c) one or more actuators, connected to each of the tactile pins, and being capable of individually controlling the movement of each tactile pin and holding each the tactile pins in a desired level;
d) a controller consisting of a processor, a memory and dedicated software, for:
   d.1) converting information to be displayed that is received from the computerized device, to activation signals;
   d.2) activating the actuators, by the activation signals, to individually control the level of each tactile pin, such that tactile pins that protrude above the touchscreen and the remaining tactile pins being below the touchscreen will represent the information to be displayed;
   d.3) holding all tactile pins in place, as long as the information to be displayed has not been changed;
   d.4) whenever receiving, from the computerized device, updated information to be displayed, refreshing the displayed information by updating the level of each tactile pin, such that tactile pins that protrude above the touchscreen and the remaining tactile pins being below the touchscreen will represent the updated information;
e) transmitting visual information received from the computerized device to the touchscreen, which corresponds to each state of tactile pins; and
f) following groping of protruding tactile pins, receiving inputs from the user in the form of touching a desired location on the touchscreen.

The tactile computing device may be implemented as:
a desktop device;
a mobile phone;
a portable computer;
a laptop computer;
a notebook;
a tablet.

A predetermined cluster of tactile pins may be controlled to:
a) protrude from the rigid surface, to form a tactile object; and
b) move as a propagating wave by actuating different pins over time a desired direction, while keeping the cluster form unchanged.

The moving cluster may be used to:
guide the user from one location of the screen to another location;
represent moving tactile objects in gaming application and computer games; and
represent different colors by different moving patterns.

### BRIEF DESCRIPTION OF THE DRAWINGS

In the drawings:

FIG. 1 illustrates a possible implementation of the tactile interface 100 of tactile computing device 90, according to an embodiment of the invention;

FIG. 2 illustrates a possible layout of a combined mode, according o an embodiment of the invention;

FIG. 3 illustrates a cross-sectional view of the MEMS array in the combined mode, according to an embodiment of the invention;

FIG. 4 illustrates an example of graphical representation of information using the tactile interface, according to an embodiment of the invention;

FIG. 5a shows an example of Excel spreadsheet with visual information;

FIG. 5b shows a tactile representation of the same spreadsheet, while using ELIA FRAMES™ Tactile Font;

FIG. 6a shows an example of monthly data distribution of sales in an enterprise; and

FIG. 6b shows a tactile representation of the same data distribution, according to an embodiment of the invention.

### DESCRIPTION OF THE INVENTION

The present invention proposes a high definition tactile interface and computing device, by which a user with visual impairment or that temporarily limited ability to watch a screen can understand vast information provided to him, activate the device and also use the interface as an input device.

The interface apparatus comprises an array of tactile pins that can be pushed up to several levels by the device itself and to protrude from a rigid surface via holes in the surface, or downwards to be below the surface by using currents or signals and a mechanical component that holds the pins in place or pushed downwards by user. This is performed by applying very small pins with actuators that can move upwards to various predetermined heights above the surface according to corresponding activation signals, received from a computerized device. In addition, the pins, or some of them, can be pushed downwards by the user to provide inputs. In order to create a tactile image, several pins are leveled to various heights, thereby creating embossed images. By pushing specific pins downwards, the actuators are adapted to generate signals that are input to the computer's operating system and the user can indicate his selection. This is similar to clicking on a mouse button or touching a touchscreen.

According to an embodiment of the invention, the rigid surface can be a conventional touchscreen, for allowing the user to touch desired locations with his finger, in order to provide inputs to the computerized device. In this embodiment, the feels the protruding pins with his finger and is guided by them to the appropriate location. Since the touchscreen is capable of displaying visible information (in addition to receiving inputs resulting from touching), this embodiment allows two different users to use the same interface apparatus: one user, who is visually impaired, receives information by his finger via the tactile pins; and another user who can see, receives information which is conventionally displayed on the touchscreen.

This mode of operation also allows users with limited vision to benefit from the combination of tactile pins and visual display capabilities of the touchscreen. These users cannot see clearly while looking on the touchscreen from a normal distance (about 40-50 cm above the touchscreen)—they must reduce the distance to 5 cm in order to see displayed information. This is very inconvenient for them. By using the interface apparatus with touchscreen surface, a user can be guided by feeling the information delivered to him via the tactile pins and then, upon reaching a desired location on the screen (for example a virtual button or a virtual key of a virtual keyboard), to bend over and take a close look of the visual information that is currently displayed in that specific location (e.g., an icon, a symbol or a character). This allows the user to shorten the time needed to understand the exact location on the interface apparatus and perform faster.

By using these tactile pins, the user can move and modify items on the screen, provided that an application allows doing so. The array is mounted on an electric circuit that can operate as a mobile tablet or display information from an external device, such as a display screen.

One of the technologies that can be used for this implementation could be MEMS (Micro Electronic Mechanical Systems—a technology of microscopic devices, particularly those with moving parts. MEMS are made up of components between 0.001 to 0.1 mm in size, and MEMS devices generally range in size from 0.02 to 1.0 mm. They usually consist of a central unit that processes data and several components that interact with the surroundings such as micro-sensors).

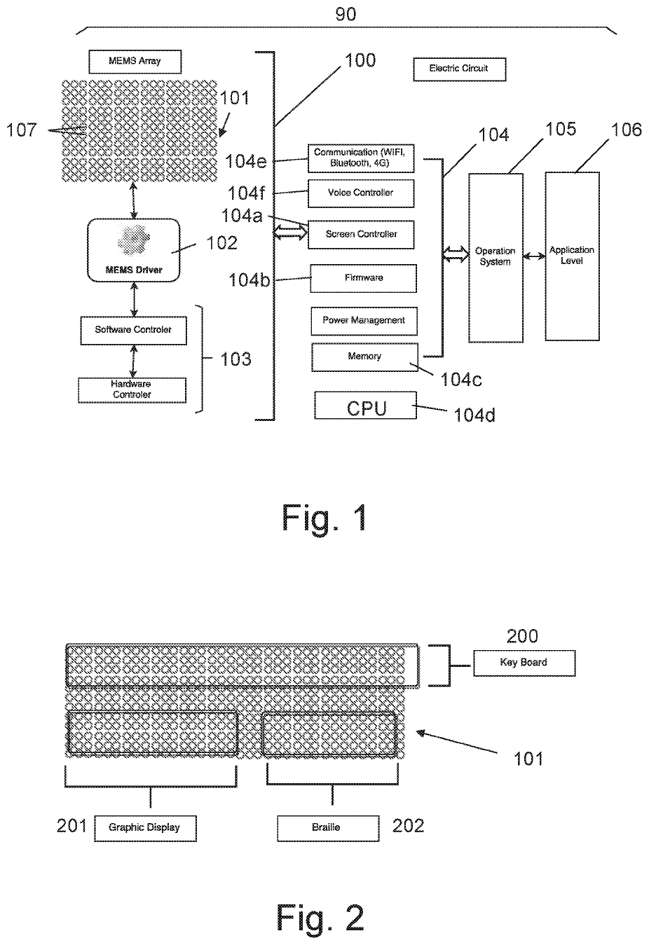

FIG. 1 illustrates a possible implementation of the tactile interface 100 of tactile computing device 90, according to an embodiment of the invention. A MEMS array 101 consists of a rigid surface from which a plurality of pins 107 can protrude to a desired height above the surface, via an array of corresponding holes (shown by circles), according to force created by a driver. This force is used to individually control each pin in the array of controllable pins is controlled by an appropriate driver (e.g., a MEMS driver) 102, which is adapted to push selected pins to protrude above the surface or pull them back to the surface (so they be less protruding or not protrude at all, if pulled below the surface). Driver 102 is controlled by a controller 103, which receives from an activation electronic circuit 104, signals representing the data to be graphically displayed via array 101.

Activation electronic circuit 104 receives the video signals (that are regularly displayed by a VGA computer screen) form the operating system 105, according to inputs received from a running application 106. These video signals are processed by a screen controller 104a according to dedicated software (firmware running on the CPU and controls the hardware components of tactile interface 100) 104b that identifies contour lines of objects (such as cell of an Excel spreadsheet, grids of a graph, bars of a histogram, etc.) and data segments (e.g., segments of a graph) from the graphical information to be displayed, decides which objects will be displayed via array 101 and converts the video signals to corresponding commands to controller 103, which in turn, activates driver 102 to push the tactile pins to a desired height above the surface. This way, the protruding pins actually serve as “tactile pixels” of array 101, which the user can feel and get the desired and information. The information is displayed via the tactile pins in a resolution that is determined by the distance between neighbouring tactile pins that protrude above the rigid surface and belong to the same object or data segment.

The MEMS technology allows to provide high resolution matrix. This will allow software flexibility to project information in a versatile manner, which is equivalent to zooming function, which helps the user to have correct interpretation of the information that is displayed. Of course, MEMS technology is not mandatory and other technologies can be used to control the movement of the tactile pins.

The pushed pins are held in place (in the desired level of protrusion) above the surface by an electro-mechanical mechanism (that will be detailed later on) in a force that will be sufficient to resist normal groping pressure. However, after groping and getting the desired information, the user will be able to push them back toward the surface in order to touch the surface and provide inputs, as will be described later on.

The various levels of pins can be used to create the sense of different colors or gradual change of the height, so as to create the sense of three dimensional objects. Also, the tactile pins can be used to display not only contour lines of objects or data segments, but also curvatures of graphic information, in order to implement three-dimensional objects, which may be stationary or moving objects.

Activation electronic circuit 104 of the tactile computing device 90 has a CPU 104d for processing data for the screen controller 104a, a local memory 104c for storing data and information to be displayed on the array and providing data to the CPU 104d, communication ports 104e and protocols (such as WIFI, Bluetooth, mobile internet, etc.) for communication. It can also be connected to an external device by USB or WiFi connection. The tactile computing device 90 runs an operating system 105, which enables it to store and operate applications 106, just like a conventional computer. Tactile computing device 90 may also comprise a voice controller 104f, for providing feedback to the user about his operations, as will be described later.

The interface apparatus has three main operational modes, which can work separately or simultaneously:

Display Mode

This mode will be used for displaying information via the tactile interface 100, which can be generated by the tactile computing device 90 itself, or can be received from an external device (similar to the function of a visual computer screen, but tactile).

Computing Mode

This mode will allow the user to activate a function (e.g., by click on one or more tactile icons) using pre-installed or downloaded applications.

Input Device Mode

This mode will allow the user to display soft buttons that operates an external device, such as a tactile computer mouse or a tactile pointing device by defining tactile contour lines of a touchpad screen, in which the user can drag his finger to emulate movements of a mouse cursor. Feedback to the user may be provided using voice applications, such as text-to-speech. Another voice application such as speech-to-text may also be used to help the user providing inputs (voice commands) after feeling the displayed information.

Combined Mode

FIG. 2 illustrates a possible layout of a combined mode, according to an embodiment of the invention. In this mode, a part of the MEMS array 101 (the tactile screen) is used to display graphical (or textual) information, while at the same time, other parts of the screen are used for other purposes, such as creating a tactile virtual keyboard board, or specially designed buttons for operating the device or a selected application, displaying Braille information, etc. Alternatively, textual information such as letters and numbers may be displayed using ELIA FRAMES™ Tactile Font which is an intuitive tactile reading system.

It is designed to be understood by touch for those who have a visual impairment, who have difficulties in learning and understanding Braille.

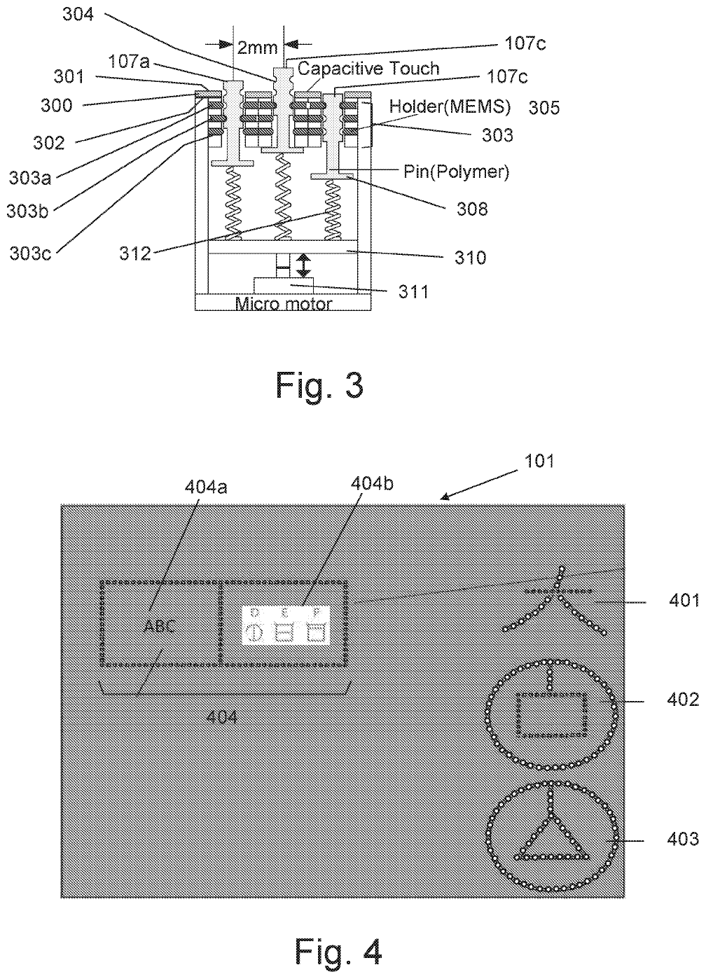

FIG. 3 illustrates a cross-sectional view of the MEMS array 101 in the combined mode, according to an embodiment of the invention. In this example, the surface from which pins 107 protrude is a touchscreen 300, which is sensitive to finger touch of the user and can provide inputs (to the operating system 105) representing the user's selection. In this example, three neighboring pins 107a-107c (which may be made for example, from plastic or any other polymer) are shown to protrude above the upper surface 301 of the touchscreen 300 (via appropriate holes 109 formed in touchscreen 300), each in different protrusion level. Each pin 107a-107c is tubular with several circumferential grooves 304 formed in predetermined spacing above each other. A layer 303 of MEMS holders arranged in vertically spaced sub-layers 303a-303c is installed subjacent to the lower surface, such that each sublayer comprises holders in different levels below the lower surface of touchscreen 300. These holders are controlled by the screen controller 104a to enter one of the grooves that corresponds to their level, depending on the vertical position of each pin 107. Each pin has a base 308, for applying upwardly or downwardly directed force for moving the pin to a desired level. All bases 308 of all pins 107 are connected by springs 312 to a common plate 310, which is pushed up and down by a micro-motor 311 according to control commands received from the screen controller 104a.

In an initial stage, motor 311 is controlled to lift plate 310, such that all springs are maximally contracted and as a result, all the pins 107 are pushed up by to maximally protrude above the upper surface 301. Upon receiving a command to display information, the screen controller 104a sends a command to the holders of layer 303a to enter the lower groove of all pins that should be in maximum protruding level, as shown with respect to pin 107b, such that they will be locked in this uppermost position. Then, the screen controller 104a sends a command to motor 311 to start lowering plate 310 to the next lower level and when this level is reached, the screen controller 104a sends a command to the holders of layer 303b to enter the intermediate groove of all pins that should be in the next (and lower) protruding level, as shown with respect to pin 107a, such that they will be locked in this position. Then, the screen controller 104a sends a command to motor 311 to continue lowering plate 310 to the next lower level and when this level is reached, the screen controller 104a sends a command to the holders of layer 303c to enter the intermediate groove of all pins that should be in the next (and lowest) level in which the pins do not protrude, as shown with respect to pin 107c, such that they will be locked in this position. Similarly, if the pins are adapted to be in more levels, this process continues. This way, the graphic information is rendered, where each pin represents a tactile pixel.

Upon detecting a change in the information to be displayed, this process is repeated, until ordering all pins 107 in new levels that correspond to the updated information.

According to another embodiment, an input may be provided from the user by pushing down selected pins 107, until they reach the upper surface 301.

The tactile computing device 90 may be implemented as a desktop device which comprises a conventional desktop computer which uses the proposed tactile interface 100 instead of a visual display screen, a mouse and a keyboard. Alternatively, the tactile computing device 90 may be implemented as a mobile phone or a portable computer such as a laptop computer, a notebook or a tablet.

FIG. 4 illustrates an example of graphical representation of information using the tactile interface 100, according to an embodiment of the invention. It can be seen it is possible to control the actuators of corresponding pins, such that they will represent tactile symbols 401-403, as well as keys 404a-404b of a virtual keypad 404.

Spacing between neighboring tactile pins is designed to allow required tactile display resolution. Also, the diameter height and level of protrusion of the tactile pins is designed to allow a user that gropes the tactile pins to touch the upper surface of the touchscreen, following groping. The sensitivity of the touchscreen to finger touching is also adapted for this purpose.

Such symbols may represent tactile programmable shortcuts that can be placed in a toolbar along one of the edges of tactile interface 100. These, tactile shortcuts guide user when using applications. Shortcuts can be programmed in advance or modified by user to speed up his use of the tactile computing device 90. Other shortcut may include zoom-in zoom-out operations and rotating items or the entire screen information, by rearranging the pins in the array according to the selected operation.

The screen controller 104a may control a cluster of pins to protrude from the rigid surface, to form a tactile object and to move in waves (i.e., to actuate different pins over time in a desired direction, while keeping the cluster form unchanged), to create the sense of movement. This effect can be used to guide the user from one location of the screen to another location. This also allows using gaming application for moving tactile objects on the screen, such as a car that moves from side to side or other moving objects. It is also possible to represent different colors by moving areas with different moving patterns.

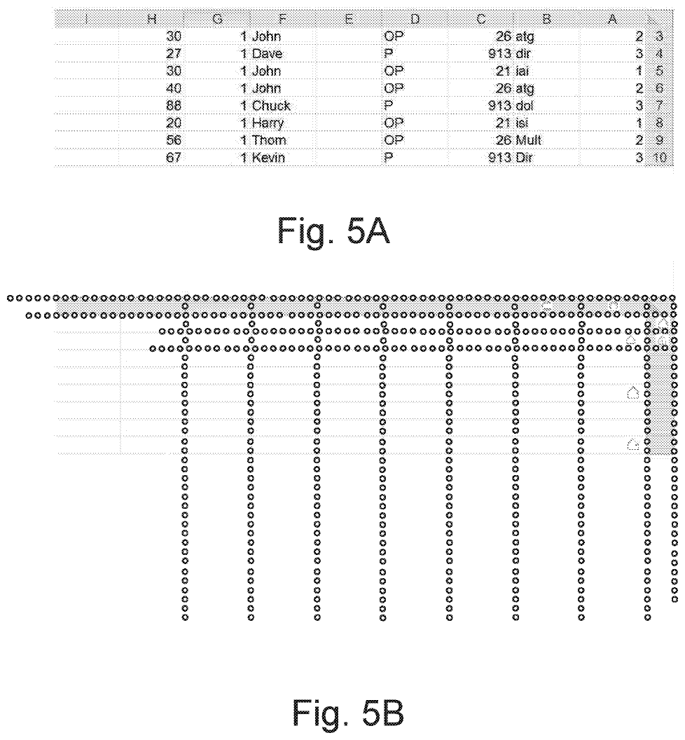

FIG. 5a shows an example of Excel spreadsheet with visual information. FIG. 5b shows a tactile representation of the same spreadsheet, while using ELIA FRAMES™ Tactile Font. In this example, the user can touch the contour pins of any cell and get a voice feedback regarding his location on the spreadsheet (e.g., “A3”). Then be can move easily to a desired cell and feel its content (in this example, the content of cell “A4” is 3= [symbol] ).

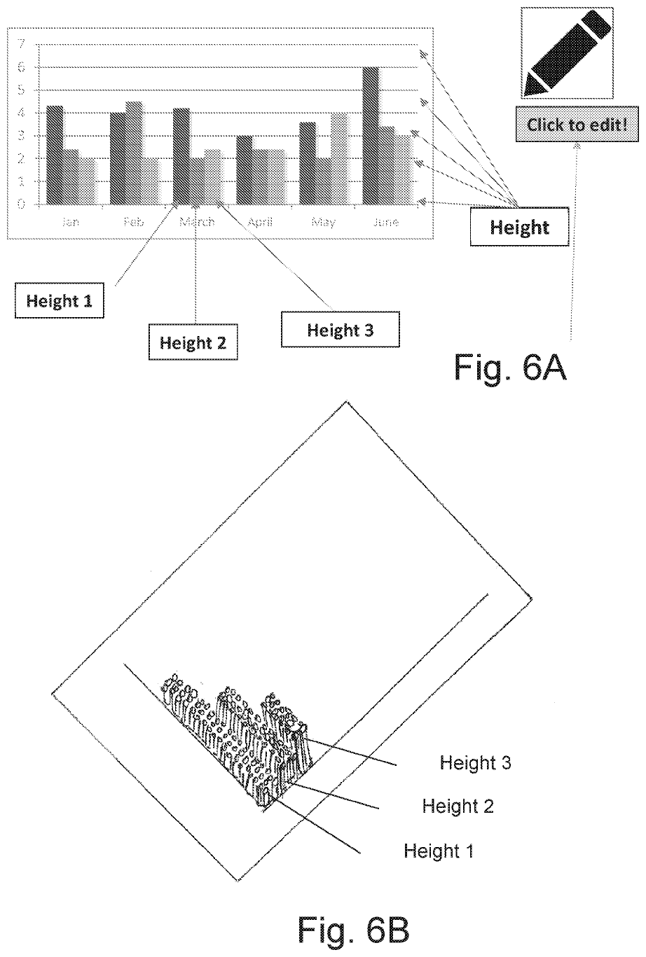

FIG. 6a shows an example of monthly data distribution of sales in an enterprise. FIG. 6b shows a tactile representation of the same data distribution, according to an embodiment of the invention. It can be seen that the three different colors in the visual representations are represented by different levels of pins, which illustrates the required information to the visually impaired user.

It should be indicated that the term “pins” is meant to include any shape of elongated elements that can protrude from the rigid surface or touchscreen via appropriate holes, and be groped by the user.

While some embodiments of the invention have been described by way of illustration, it will be apparent that the invention can be carried out with many modifications, variations and adaptations, and with the use of numerous equivalents or alternative solutions that are within the scope of persons skilled in the art, without exceeding the scope of the claims.

1. A tactile display apparatus for displaying information received from a computerized device, comprising:
a) an array of tactile pins that can be pushed to one or more levels to protrude above a rigid surface and pulled below said rigid surface, via holes in said surface, by one or more actuators, said tactile pins, when protruding above said surface, are being capable of representing said information in the form of tactile pixels that create embossed images above said surface;
b) one or more actuators, connected to each of said tactile pins, and being capable of individually controlling the movement of each tactile pin and holding each said tactile pins in a desired level;
c) a controller consisting of a processor, a memory and dedicated software, for:
c.1) converting information to be displayed that is received from said computerized device, to activation signals;
c.2) activating said actuators, by said activation signals, to individually control the level of each tactile pin, such that tactile pins that protrude above said rigid surface and the remaining tactile pins being below said rigid surface will represent the information to be displayed;
c.3) holding all tactile pins in place, as long as the information to be displayed has not been changed; and
c.4) whenever receiving, from said computerized device, updated information to be displayed, refreshing the displayed information by updating the level of each tactile pin, such that tactile pins that protrude above said rigid surface and the remaining tactile pins being below said rigid surface will represent said updated information.

2. A tactile display apparatus according to claim 1, in which the computerized device is selected from the group of:
a desktop computer;
a laptop;
a tablet;
a smartphone.

3. A tactile display apparatus according to claim 1, further comprising controllable holders for holding the tactile pins in place by applying lateral force on said tactile pins, as long as the information to be displayed has not been changed.

4. A tactile display apparatus according to claim 1, in which the actuators and controllable holders are implemented by Micro Electronic Mechanical Systems (MEMS).

5. A tactile display apparatus according to claim 1, in which the information to be displayed, received from a computerized device, is in the form of video signals.

6. A tactile display apparatus according to claim 1, in which the displayed information is textual, graphical or a combination thereof.

7. A tactile display apparatus according to claim 1, in which the displayed information includes:
contour lines of graphical objects;
a combination of contour lines of graphical objects and textual characters contained therein;
grids of a graph;
bars of a histogram; and
graphical data segments.

8. A tactile display apparatus according to claim 1, in which the protruding pins serve as “tactile pixels” representing the information to be displayed.

9. A tactile display apparatus according to claim 1, in which the information to be displayed is refreshed according to a predetermined resolution being the distance between neighboring tactile pins that protrude above the rigid surface.

10. A tactile display apparatus according to claim 1, in which different levels of pins are used to:
create a sense of different colors;
create gradual change of the height, to thereby create a sense of three-dimensional objects;
represent curvatures of graphic information.

11. A tactile display apparatus according to claim 1, in which the rigid surface is a touchscreen, which is connected to the computerized device and form a tactile interface apparatus, which is adapted to:
a) display visual information received from said computerized device; and
b) following groping of protruding tactile pins, receive inputs from the user in the form of touching a desired location on said touchscreen.

12. A tactile interface apparatus according to claim 11, further comprising a voice controller, for:
providing voice feedback to the user regarding inputs be provided or his location on the touchscreen;
providing voice guidance to said user regarding how to provide inputs.

13. A tactile interface apparatus according to claim 11, in which the tactile pins define tactile contour lines of a touchpad, in which the user can drag his finger to emulate movements of a mouse cursor.

14. A tactile interface apparatus according to claim 11, in which the tactile pins define tactile contour lines of a virtual key of a keyboard or a virtual button.

15. A tactile interface apparatus according to claim 14, in which the tactile pins inside the contour lines are controlled to define a symbol representing one of the following:
graphical information;
textual information;
Braille characters;
ELIA FRAMES™ characters;
programmable shortcuts;
tactile toolbar;
tactile keys of a virtual keyboard.

16. A tactile computerized device which comprises a tactile interface apparatus for displaying information and receive inputs from a user, comprising:
a) a touchscreen for receiving inputs from said user and for displaying visual data;
b) an array of tactile pins that can be pushed to one or more levels to protrude above said touchscreen and pulled below said touchscreen, via holes in said surface, by one or more actuators, said tactile pins, when protruding above said surface, are being capable of representing said information in the form of tactile pixels that create embossed images above said surface;
c) one or more actuators, connected to each of said tactile pins, and being capable of individually controlling the movement of each tactile pin and holding each said tactile pins in a desired level;
d) a controller consisting of a processor, a memory and dedicated software, for:
d.1) converting information to be displayed that is received from said computerized device, to activation signals;
d.2) activating said actuators, by said activation signals, to individually control the level of each tactile pin, such that tactile pins that protrude above said touchscreen and the remaining tactile pins being below said touchscreen will represent the information to be displayed;
d.3) holding all tactile pins in place, as long as the information to be displayed has not been changed;
d.4) whenever receiving, from said computerized device, updated information to be displayed, refreshing the displayed information by updating the level of each tactile pin, such that tactile pins that protrude above said touchscreen and the remaining tactile pins being below said touchscreen will represent said updated information;
e) transmitting visual information received from said computerized device to said touchscreen, which corresponds to each state of tactile pins; and
f) following groping of protruding tactile pins, receiving inputs from the user in the form of touching a desired location on said touchscreen.

17. The tactile computing device according to claim 16, implemented as:
a desktop device;
a mobile phone;
a portable computer;
a laptop computer;
a notebook;
a tablet.

18. A tactile interface apparatus according to claim 15, in which a predetermined cluster of tactile pins is controlled to:
a) protrude from the rigid surface, to form a tactile object; and
b) move as a propagating wave by actuating different pins over time in a desired direction, while keeping the cluster form unchanged.

19. A tactile interface apparatus according to claim 18, in which the moving cluster is used to:
guide the user from one location of the screen to another location;
represent moving tactile objects in gaming application and computer games; and
represent different colors by different moving patterns.
